(19) United States
(12) Patent Application Publication
(10) Pub. No.: US 2026/0182457 A1
(43) Pub. Date: Jun. 25, 2026

(54) POWER DELIVERY FOR 3-DIMENSIONAL CHIPLET STACKS

(71) Applicant: INTERNATIONAL BUSINESS MACHINES CORPORATION, ARMONK, NY (US)

(72) Inventors: Todd Edward Takken, Brewster, NY (US); John Knickerbocker, Monroe, NY (US); Mukta Ghate Farooq, Hopewell Junction, NY (US); John W. Golz, Hopewell Junction, NY (US); Keiji Matsumoto, Yokohama-shi (JP)

(21) Appl. No.: 19/001,336

(22) Filed: Dec. 24, 2024

(51) Int. Cl. H01L 25/18; H01L 23/00; H01L 23/373; H01L 23/427; H01L 25/00; H01L 25/07

(52) U.S. Cl. CPC H10W 90/00; H10W 40/73; H10W 40/254; H10W 72/248; H10W 90/26; H10W 90/297; H10W 90/722; H10W 90/724

(57) ABSTRACT

A semiconductor device includes a at least one die stack, and one or more peripheral interconnect structures surrounding one or more sides of the at least one die stack. The one or more peripheral interconnect structures are assembled in a perpendicular orientation to a functional circuit layer of the at least one die stack.

### BACKGROUND

### Technical Field

The present disclosure generally relates to semiconductors, and more particularly, to power delivery for 3-dimensional chiplet stack structure, and methods of creation thereof.

### Description of Related Art

The continuous miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip.

### SUMMARY

According to an embodiment, a semiconductor device includes at least one die stack, and one or more peripheral interconnect structures surrounding one or more sides of the at least one die stack. The one or more peripheral interconnect structures are assembled in a perpendicular orientation to a functional circuit layer of the at least one die stack.

In one embodiment, the one or more peripheral interconnect structures includes at least one of: a peripheral power delivery interconnect structure, a peripheral cooling interconnect structure, a peripheral clocking interconnect structure, and a peripheral signal interconnect structure.

In one embodiment, the semiconductor device includes a power delivery chiplet located within the at least one die stack. The power delivery chiplet is connected at a periphery of the at least one die stack to at least one of the one or more peripheral interconnect structures.

In one embodiment, the semiconductor device includes a substrate. The substrate is at least one of: a glass, silicon, an organic electrically insulating material, and an inorganic electrically insulating material.

In one embodiment, the semiconductor device includes a substrate. The substrate is a thermal conductive material, wherein the substrate is at least one of: diamond, AlN, and SiN, and wherein the substrate comprises oscillating heat pipes.

In one embodiment, the power delivery chiplet is a horizontal power delivery chiplet. The power delivery chiplet is integrated in the one or more die stacks.

In one embodiment, the semiconductor device includes circuit layers through one or more vertical connections in the at least one die stack, and an interposer. The interposer is a horizontal high-bandwidth wiring layer, and the circuit layers comprise at least one of: high bandwidth (BW) layers and short connection layers.

In one embodiment, the semiconductor device includes circuit stack layers through one or more horizontal connections in the at least one die stack, and an interposer. The interposer is a horizontal high-bandwidth wiring layer, and the circuit layers comprise at least one of: high bandwidth (BW) layers and short connection layers.

In one embodiment, the semiconductor device includes high-bandwidth circuit layers with low latency. The high-bandwidth circuit layers comprise connections with less than 25 microns per layer.

In one embodiment, the one or more die stack comprises at least one of: a transistor, coils, magnetic layers, decoupling capacitors, electrical conductor elements, and thermal conducting elements.

In one embodiment, the power delivery chiplet comprises inductors, power delivery circuits, signal delivery circuits, electrical shielding, magnetic shielding, and cooling structures.

In one embodiment, the semiconductor device includes electrical and optical communication links. The electrical and optical communication links are located in at least one of: an interposer, a cooling unit, and a power feed unit.

In one embodiment the at least one die stack comprises at least one of: a memory, a pass-throughs of power line, and a pass-through of signal line.

According to an embodiment, method for fabrication of a semiconductor device includes forming at least one die stack, and forming one or more peripheral interconnect structures surrounding one or more sides of the at least one die stack. The one or more peripheral interconnect structures are assembled in a perpendicular orientation to a functional circuit layer of the at least one die stack.

In one embodiment, the method includes forming a power delivery chiplet located within the at least one die stack, and connecting the power delivery chiplet at a periphery of the at least one die stack to at least one of the one or more peripheral interconnect structures.

In one embodiment, the method includes forming a substrate. The substrate is at least one of: a glass, silicon, an organic electrically insulating material, and an inorganic electrically insulating material.

In one embodiment, the method includes forming a substrate. The substrate is a thermal conductive material, wherein the substrate is at least one of: diamond, AlN, and SiN, and wherein the substrate comprises oscillating heat pipes.

In one embodiment, the method includes forming circuit layers through one or more vertical connections in the at least one die stack, and forming an interposer. The interposer is a horizontal high-bandwidth wiring layer, and the circuit layers comprise at least one of: high bandwidth (BW) layers and short connection layers.

In one embodiment, the method includes forming circuit stack layers through one or more horizontal connections in the at least one die stack, and forming an interposer. The interposer is a horizontal high-bandwidth wiring layer, and the circuit layers comprise at least one of: high bandwidth (BW) layers and short connection layers.

According to an embodiment, a semiconductor device includes a die stack, and a peripheral power delivery interconnect chiplet surrounding one or more sides of the at least one die stack. The power delivery chiplet is a horizontal power delivery chiplet, wherein the power delivery chiplet is integrated in the die stack.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates a conventional packaged semiconductor device with orthogonal bridge packaging.

FIGS. 1B-1D illustrate conventional packaged inductors with orthogonal packaging.

FIGS. 2A-2E illustrate a semiconductor device, in accordance with some embodiments.

FIGS. 3A-3B illustrate an exemplary power delivery chip of the semiconductor device, in accordance with some embodiments.

FIG. 4 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

According to an embodiment, a semiconductor device includes at least one die stack, and one or more peripheral interconnect structures surrounding one or more sides of the at least one die stack. The one or more peripheral interconnect structures are assembled in a perpendicular orientation to a functional circuit layer of the at least one die stack. The peripheral interconnect structures work to supply power to the die stack.

In one embodiment, the one or more peripheral interconnect structures includes at least one of: a peripheral power delivery interconnect structure, a peripheral cooling interconnect structure, a peripheral clocking interconnect structure, and a peripheral signal interconnect structure. The power delivery chip supplies power to the die stack.

In one embodiment, the semiconductor device includes a power delivery chiplet located within the at least one die stack. The power delivery chiplet is connected at a periphery of the at least one die stack to at least one of the one or more peripheral interconnect structures. Thus, the power delivery chiplet is connected to various components of the semiconductor device.

In one embodiment, the semiconductor device includes a substrate. The substrate is at least one of: a glass, silicon, an organic electrically insulating material, and an inorganic electrically insulating material. The substrate can facilitate electrical connectivity.

In one embodiment, the semiconductor device includes a substrate. The substrate is a thermal conductive material, wherein the substrate is at least one of: diamond, AlN, and SiN, and wherein the substrate comprises oscillating heat pipes. The substrate can facilitate heat dissipation.

In one embodiment, the power delivery chiplet is a horizontal power delivery chiplet. The power delivery chiplet is integrated in the one or more die stacks. The horizontal power delivery chips work to supply power to 3D chip/chiplet stacks.

In one embodiment, the semiconductor device includes circuit layers through one or more vertical connections in the at least one die stack, and an interposer. The interposer is a horizontal high-bandwidth wiring layer, and the circuit layers comprise at least one of: high bandwidth (BW) layers and short connection layers. The vertical power delivery chips work to supply power to 3D chip/chiplet stacks.

In one embodiment, the semiconductor device includes circuit stack layers through one or more horizontal connections in the at least one die stack, and an interposer. The interposer is a horizontal high-bandwidth wiring layer, and the circuit layers comprise at least one of: high bandwidth (BW) layers and short connection layers. The interposer can further facilitate heat dissipation and electrical connectivity.

In one embodiment, the semiconductor device includes high-bandwidth circuit layers with low latency. The high-bandwidth circuit layers comprise connections with less than 25 microns per layer. High BW circuit layers can enhance electrical connections.

In one embodiment, the one or more die stack comprises at least one of: a transistor, coils, magnetic layers, decoupling capacitors, electrical conductor elements, and thermal conducting elements. Various types of semiconductor devices can be inserted into the die stack.

In one embodiment, the power delivery chiplet includes inductors, power delivery circuits, signal delivery circuits, electrical shielding, magnetic shielding, and cooling structures. The power delivery chiplet can include various types of devices.

In one embodiment, the semiconductor device includes electrical and optical communication links. The electrical and optical communication links are located in at least one of: an interposer, a cooling unit, and a power feed unit. The electrical and optical physical layers can be inserted into the device.

In one embodiment the at least one die stack comprises at least one of: a memory, a pass-throughs of power line, and a pass-through of signal line. A memory or a CPU can be [protected by the semiconductor device.

According to an embodiment, method for fabrication of a semiconductor device includes forming at least one die stack, and forming one or more peripheral interconnect structures surrounding one or more sides of the at least one die stack. The one or more peripheral interconnect structures are assembled in a perpendicular orientation to a functional circuit layer of the at least one die stack. The peripheral interconnect structures work to supply power to the die stack.

In one embodiment, the method includes forming a power delivery chiplet located within the at least one die stack, and connecting the power delivery chiplet at a periphery of the at least one die stack to at least one of the one or more peripheral interconnect structures. The power delivery chiplet supplies power to the die stack.

In one embodiment, the method includes forming a substrate. The substrate is at least one of: a glass, silicon, an organic electrically insulating material, and an inorganic electrically insulating material. The substrate can facilitate electrical connectivity.

In one embodiment, the method includes forming a substrate. The substrate is a thermal conductive material, wherein the substrate is at least one of: diamond, AlN, and SiN, and wherein the substrate comprises oscillating heat pipes. The substrate can facilitate heat dissipation.

In one embodiment, the method includes forming circuit layers through one or more vertical connections in the at least one die stack, and forming an interposer. The interposer is a horizontal high-bandwidth wiring layer, and the circuit layers comprise at least one of: high bandwidth (BW) layers and short connection layers. The interposer can facilitate heat dissipation and electrical connectivity.

In one embodiment, the method includes forming circuit stack layers through one or more horizontal connections in the at least one die stack, and forming an interposer. The interposer is a horizontal high-bandwidth wiring layer, and the circuit layers comprise at least one of: high bandwidth (BW) layers and short connection layers. High BW circuit layers can enhance electrical connections.

According to an embodiment, a semiconductor device includes a die stack, and a peripheral power delivery interconnect chiplet surrounding one or more sides of the at least one die stack. The power delivery chiplet is a horizontal power delivery chiplet, wherein the power delivery chiplet is integrated in the die stack. The peripheral interconnect structures work to supply power to the die stack.

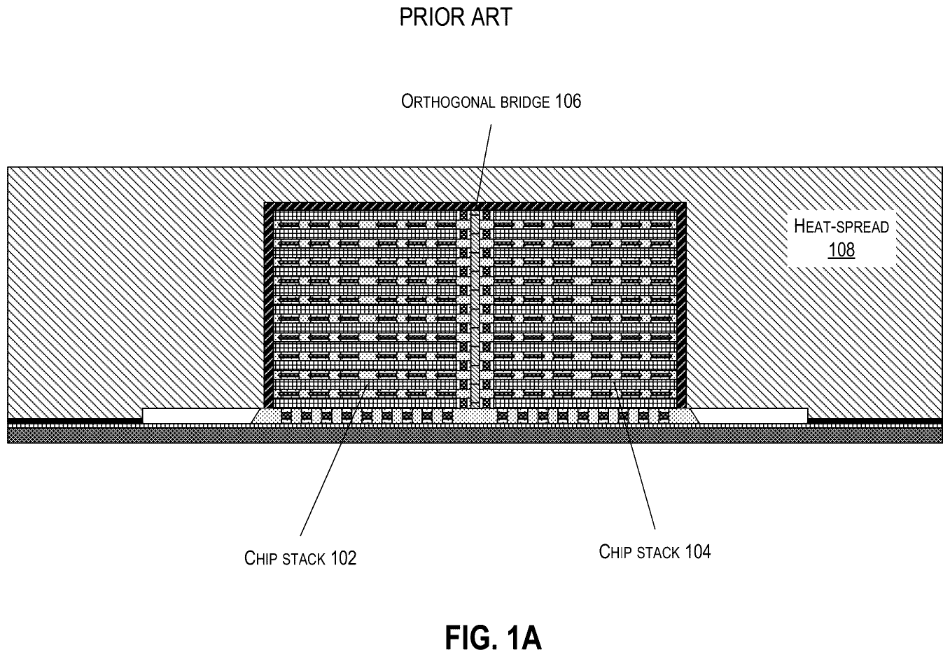

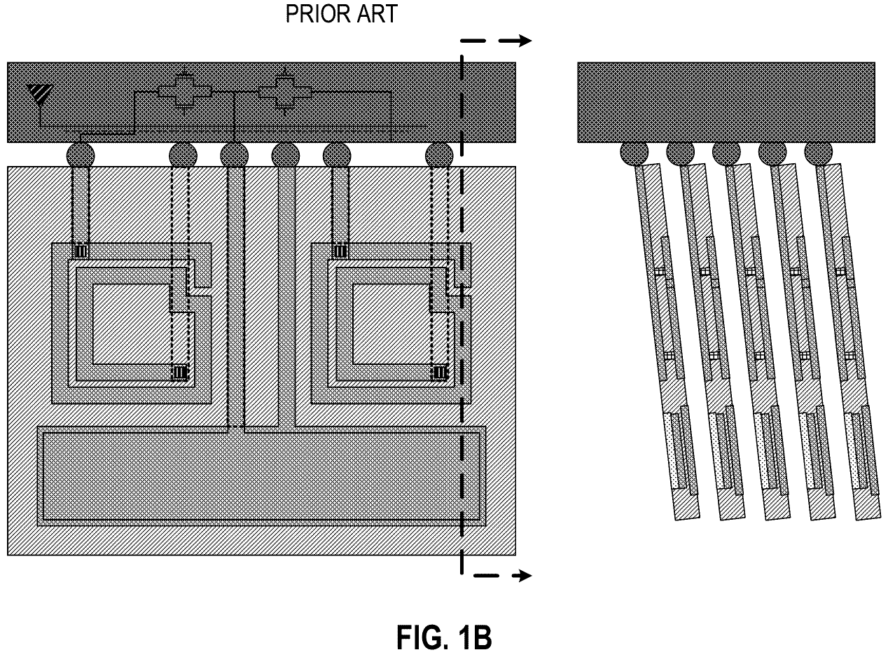

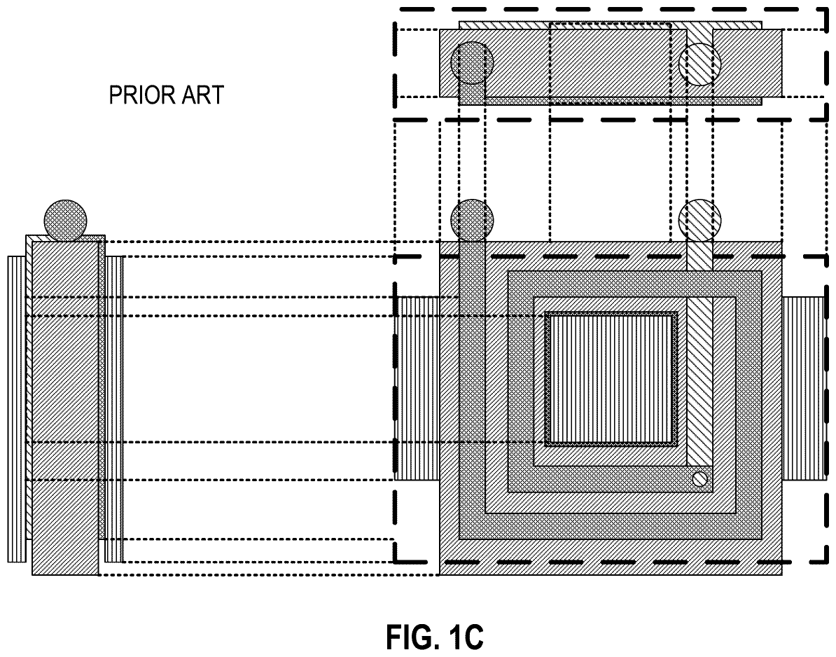

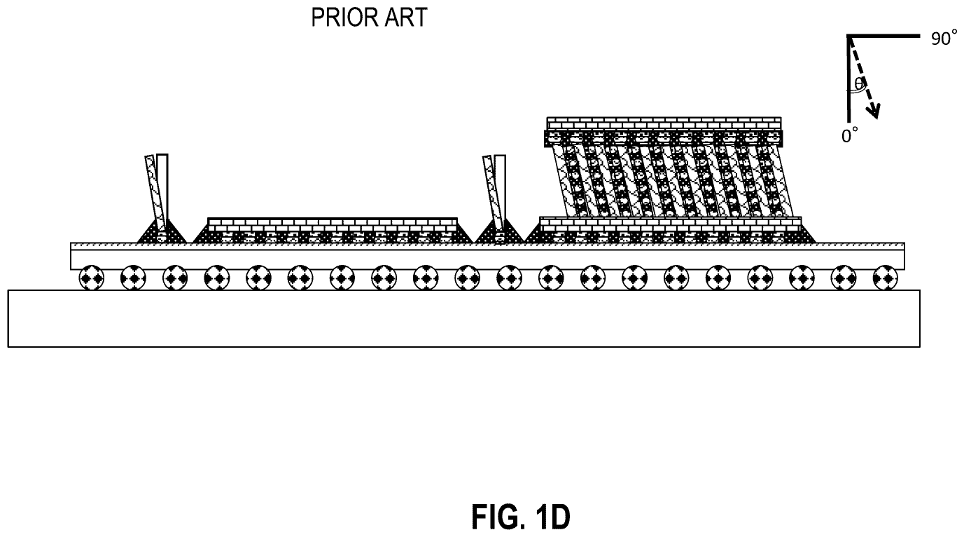

FIG. 1A illustrates a conventional packaged semiconductor device with orthogonal bridge packaging. In semiconductor device packaging, conventional designs utilize an orthogonal bridge to connect chip stack 102 and chip stack 104. The orthogonal bridge 106 is responsible for delivering power, ground, and signals between the two chip stacks. By relying on the bridge, the packaged device eliminates the need for through-silicon vias (TSVs) in the chip stacks, a distinction from designs that incorporate TSVs for vertical interconnects. In these designs, interconnects are fabricated on the lateral surfaces of chip stack 102 and chip stack 104, enabling electrical routing along the sides rather than through the chips. Thermal management is achieved through the direct attachment of a heat spreader 108 to chip stack 102 and chip stack 104. Such a configuration allows for heat dissipation across the stacks.

FIGS. 1B-1D illustrate conventional packaged inductors with orthogonal packaging. Conventional in-plane inductors occupy more than 50% of the interposer area or the chip area, significantly limiting the available space for other components and reducing overall integration density. To address this issue, orthogonal inductors have been introduced, which are positioned either above or below the chip. This approach effectively reduces the lateral footprint of the inductors, freeing up valuable chip or interposer area for other functions and increasing the efficiency of the design.

However, while orthogonal inductors alleviate some of the space constraints for single-layer chips, they are insufficient for 3D chip or chiplet stacks. In 3D structures, the vertical stacking of multiple chips introduces new spatial and design challenges that go beyond the capacity of orthogonal inductors. The increased density and complexity of interconnections in 3D stacks require advanced inductor solutions capable of maintaining high performance while addressing the constraints of vertical integration. Consequently, a more sophisticated approach is needed to optimize inductor placement and functionality for 3D chip or chiplet stack applications.

The disclosed semiconductor device introduces a power delivery architecture for 3D chip/chiplet stacks by employing a combination of vertical power delivery chips and horizontal power delivery chips. The design addresses the growing power delivery challenges in densely integrated 3D structures, ensuring efficient power distribution throughout the stacked chips or chiplets. Power delivery is achieved using power delivery chips positioned at the side of the 3D stacked chips/chiplets. The vertical power delivery chips facilitate the vertical transfer of power through the layers of the stack, ensuring each chip layer receives the required power. Meanwhile, horizontal power delivery chips manage the lateral distribution of power, complementing the vertical delivery and ensuring consistent power delivery across the entire stack.

By placing power delivery chips at the sides of the 3D stack, the design eliminates the need for extensive internal power delivery networks within the stack itself. This approach reduces the reliance on through-silicon vias (TSVs) for power delivery, minimizing their associated fabrication complexities and potential thermal and electrical challenges. Furthermore, the separation of power delivery functionality into dedicated chips enhances the scalability and modularity of the design, making it suitable for advanced semiconductor applications where power efficiency and integration density are critical. Such a combination of vertical and horizontal power delivery chips ensures that the power needs of each chip layer in the stack are met effectively, paving the way for more robust, efficient, and scalable 3D chip/chiplet stack designs.

Accordingly, the teachings herein provide methods and systems of power delivery for 3-dimensional chiplet stack structure. The techniques described herein may be implemented in a number of ways. Example implementations are provided below with reference to the following figures.

### Example Power Delivery for 3-Dimensional Chiplet Stack Structure

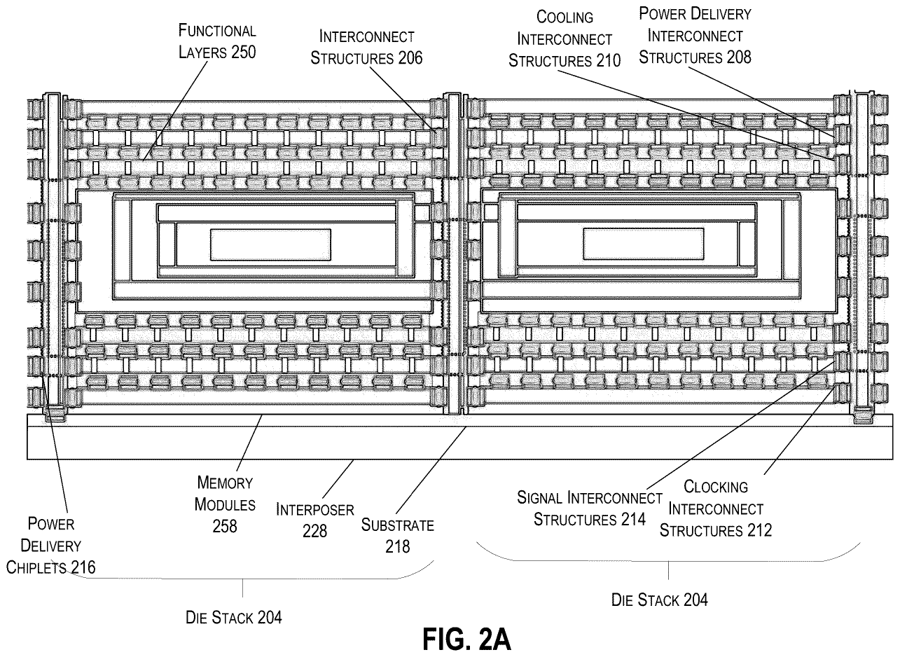

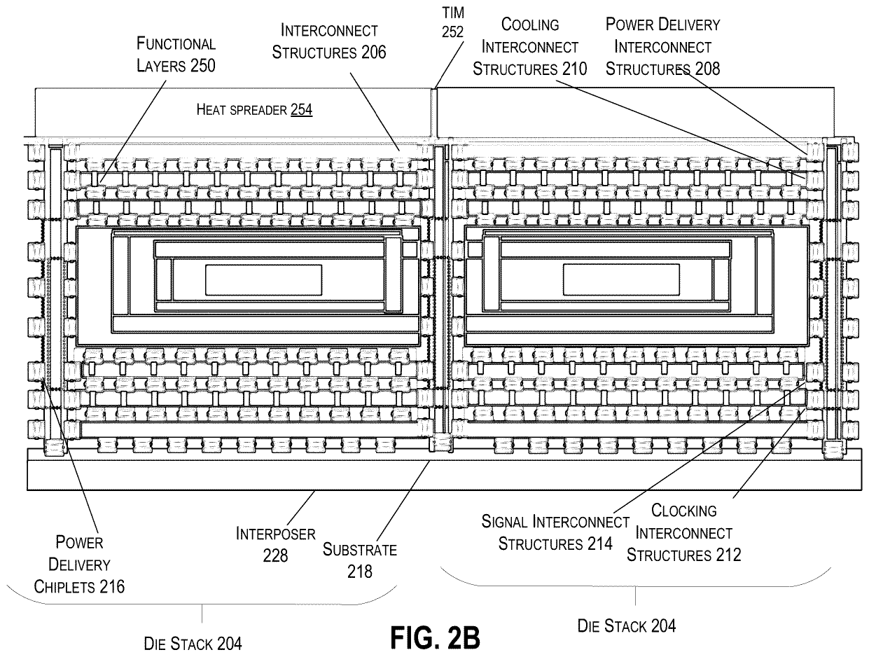

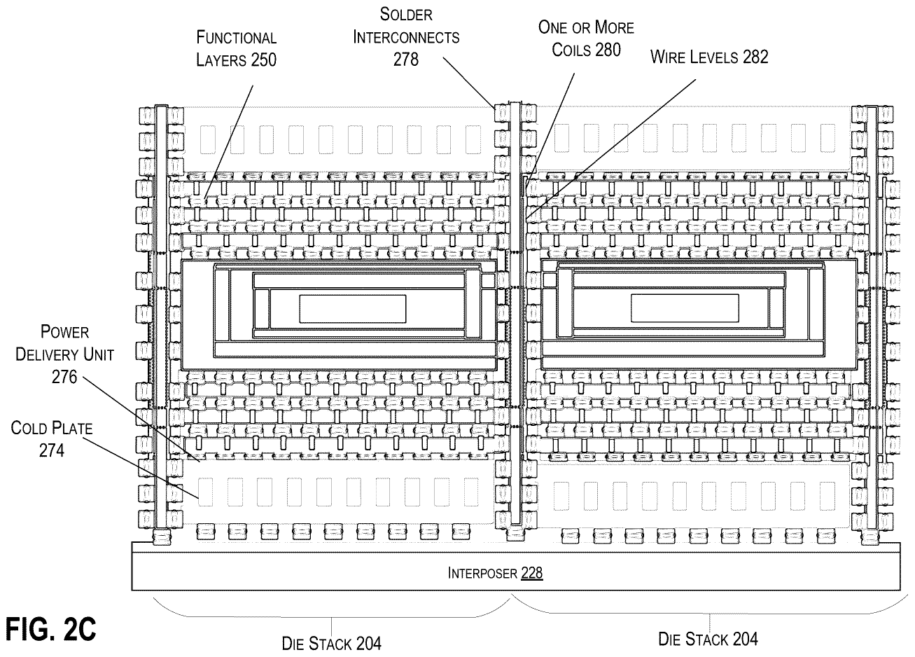

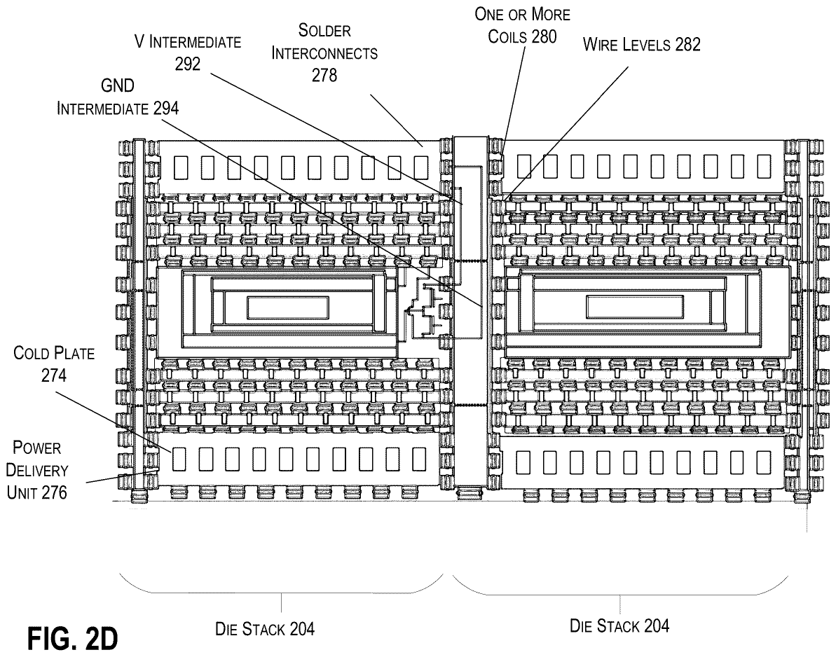

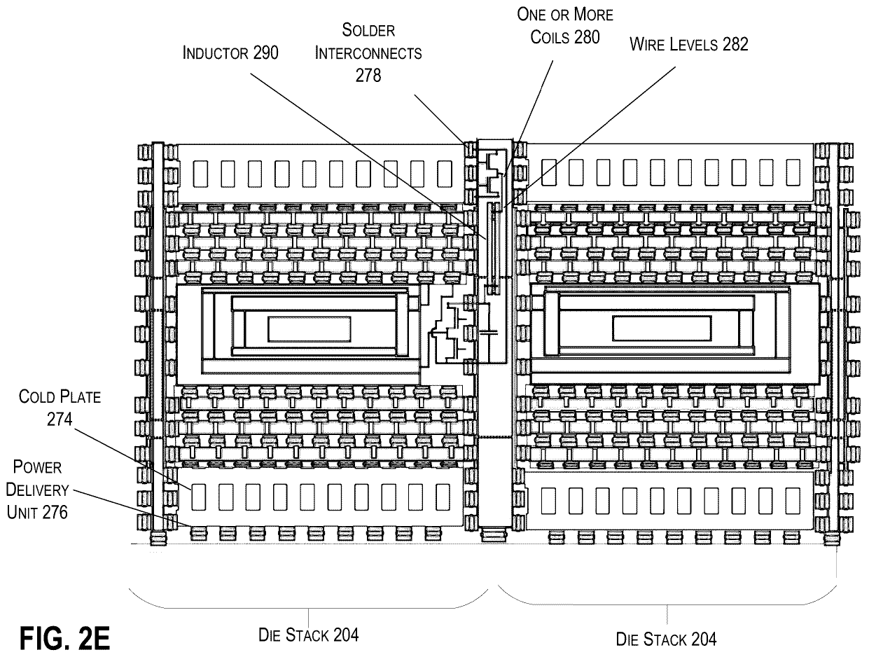

Reference now is made to FIGS. 2A-2C, which are simplified cross-sections view of a semiconductor device, consistent with an illustrative embodiment. Referring to FIG. 2A now, in some embodiments, the semiconductor device includes at least one die stack 204 including functional layers 250, which can be vertically arranged functional circuit layers, designed for high-density integration and enhanced data processing capabilities. The die stack 204 forms the primary building blocks of the device, offering functionality for computation, storage, or signal processing. Surrounding the die stack 204 on one or more sides are power delivery, cooling, clocking, or signal interconnect structures, interconnect structures 206. The interconnect structures 206 (also referred to as peripheral interconnect structures 206) are assembled in a perpendicular orientation to the functional layers 250, e.g., functional circuit layers, within the die stack 204. The perpendicular arrangement reduces the complexity of traditional horizontal interconnections and enhances vertical connectivity, thereby optimizing the overall efficiency of signal and power distribution in three-dimensional (3D) architectures.

In some embodiments, the interconnect structures 206 surrounding the die stack 204 provide functionalities for the operation of semiconductor devices. The interconnect structures 206 can include power delivery interconnect structures 208, cooling interconnect structures 210, clocking interconnect structures 212, and signal interconnect structures 214. The power delivery interconnect structures 208 are responsible for distributing energy to the functional layers 250 of the die stack 204. Cooling interconnect structures 210 manage thermal dissipation, ensuring the device remains within safe operating temperatures. Clocking interconnect structures 212 provides synchronized timing signals to maintain proper circuit functionality, while signal interconnect structures 214 enable high-speed communication between different components of the device. By isolating and optimizing these functionalities, the semiconductor device ensures reduced interference between operations, enhanced modularity, and improved overall performance.

In some embodiments, the semiconductor device includes power delivery chiplets 216 positioned at the sides of die stack 204. These power delivery chiplets 216 functions as vertical power delivery chips, supplying power directly to the die stack 204 while minimizing energy losses and improving reliability. The design localizes power management to the periphery of the stack, simplifying internal routing and enabling consistent power delivery across all functional layers 250. The power delivery chiplets 216 are mounted on a substrate 218 composed of materials such as glass, silicon, or organic insulating compounds. High thermal conductivity materials, such as diamond, aluminum nitride (AlN), or silicon nitride (SiN), can be used to enhance thermal management. The substrate 218 is designed to be sufficiently thick, providing robust thermal conduction both laterally and vertically. To further enhance thermal performance, the substrate 218 can incorporate active thermal management features, such as oscillating heat pipes, which efficiently transfer heat away from high-power-density regions.

In some embodiments, the power delivery chiplets 216 also facilitate horizontal power delivery chiplets. The horizontal power delivery chiplets complement the vertical power delivery system, ensuring efficient lateral distribution of power to functional layers within the die stack 204. The dual power delivery architecture minimizes voltage drops and enhances power efficiency throughout the device. The horizontal power delivery chiplets can be integrated directly within the die stack 204, leveraging the same high thermal conductivity substrate to ensure consistent thermal and electrical performance across the device.

In some embodiments, the semiconductor device incorporates structures that enable high bandwidth (BW) and short connections between functional circuit layers through vertical interconnects. The vertical interconnects interface with an interposer 228 or alternative horizontal high-bandwidth wiring layers, such as bridges or glass substrates. The structures achieve rapid data transfer while maintaining low latency, which is essential for high-performance computing and data-intensive applications. Similarly, the semiconductor device includes horizontal connection layers that enable high bandwidth and short communication paths between circuit stack layers, further enhancing connectivity within the device.

High bandwidth (BW) layers refer to interconnect layers within a semiconductor device that are optimized for rapid data transfer and communication between different components. These layers are characterized by their ability to handle large amounts of data simultaneously, enabling efficient processing in applications that require high-speed operations, such as artificial intelligence, machine learning, and data analytics. High bandwidth layers typically utilize wide and low-resistance pathways to minimize signal degradation and latency. Short connection layers, on the other hand, are interconnect layers designed to provide direct and efficient connections between nearby components within the semiconductor device. By minimizing the physical distance between connected elements, short connection layers reduce signal propagation delays and power losses, enhancing overall device performance. These layers are particularly important in densely packed 3D chip/chiplet architectures, where space and efficiency are critical. Together, high bandwidth layers and short connection layers ensure that semiconductor devices achieve both high-speed data processing and energy-efficient operation, making them vital for next-generation computing and communication technologies.

In some embodiments, high bandwidth with low latency is a defining feature of the semiconductor device, achieved through connections less than 25 microns per layer. This configuration allows components, such as CPUs, GPUs, accelerators, and memory units, to be located in close proximity to one another. The reduced physical distance between these components minimizes signal propagation delays and power inefficiencies, enhancing computation performance. This design is particularly advantageous for applications requiring high-speed data processing and seamless integration between multiple functional units.

In some embodiments, the semiconductor device includes functional structures such as field-effect transistors (FETs), coils, magnetic layers, decoupling capacitors, electrical conductors, and thermal conducting elements. These structures are fabricated from advanced materials, such as copper, and are integrated with additional features like heat pipes to support the electrical and thermal requirements of the device. The integration of these functional elements ensures the device operates efficiently and reliably under high-performance conditions, providing the necessary support for complex operations.

In some embodiments, the power delivery chiplets 216, which can be vertical power delivery chiplets, incorporated in the device include advanced components such as inductors, power delivery circuits, signal delivery circuits, electrical shielding, magnetic shielding, and cooling structures. Such features enhance the robustness of the power delivery system by ensuring reliable energy distribution, mitigating electromagnetic interference, and managing thermal loads effectively. The combination of these features allows the device to maintain stable operation even under high power demands and challenging environmental conditions.

In some embodiments, the semiconductor device integrates electrical and optical communication links, communication links, located within interposer 228, cooling units, or power feed units. The communication links enable high-speed data transmission and seamless integration of electrical and optical technologies, which is important for modern semiconductor applications requiring large-scale data processing and connectivity. By incorporating both electrical and optical PHYs, the device achieves superior communication performance and supports a wide range of applications, from artificial intelligence to telecommunications.

In some embodiments, the die stack 204 can include standard off-the-shelf or custom memory modules 258, as well as regular pass-throughs for power line and signal line. These features ensure compatibility with existing memory technologies while maintaining efficient and reliable power and signal flow throughout the stack. The inclusion of standard memory options allows the device to be integrated into various systems without requiring extensive customization, thereby reducing development time and costs.

In some embodiments, grounding, isolation, and shielding structures, such as Faraday cages, are incorporated into the semiconductor device based on specific application requirements. These structures protect sensitive components from electromagnetic interference, ensuring stable operation and enhancing the device's electromagnetic compatibility. By minimizing external disturbances, these shielding mechanisms contribute to the overall reliability and performance of the semiconductor device.

In some embodiments, the semiconductor device features advanced voltage regulation) designed for optimal power conversion and reduced voltage proximity to circuits or loads. This voltage regulation alleviates IR drops, improving the stability and efficiency of power delivery. By ensuring that power is delivered at the correct voltage levels, the device maintains consistent operation and prevents damage to sensitive components, further enhancing its reliability and lifespan.

In some embodiments, power delivery, cooling, clocking, or signal interconnect structures, whether functioning together or independently, surround one or more sides of the die stack 204 and are assembled in a perpendicular orientation to the functional circuit layers within the side tacks. This configuration optimizes the use of available space and ensures efficient functionality for each interconnect structure 206. For example, power delivery interconnect structures 208 provide direct and efficient power delivery to the die stack 204, while cooling interconnect structures 210 manage heat generated during operation. Clocking interconnect structures 212 ensure proper timing synchronization across the device, and signal interconnect structures 214 support high-speed data transfer between components.

In some embodiments, power delivery chiplets 216 connected to the sides of the die stack 204 enhance power distribution by eliminating the need for extensive internal power routing. The power delivery chiplets 216, when combined with the substrate 218, improve thermal conductivity and mechanical stability. Substrate 218 such as glass, silicon, or organic electrically insulating materials ensures electrical isolation, while high thermal conductivity materials like diamond, AlN, or SiN provide superior heat dissipation. Additionally, the integration of oscillating heat pipes into the substrate 218 enables active thermal management, allowing the device to operate at higher power densities without overheating.

In some embodiments, horizontal power delivery chiplets, integrated into the die stack 204, further enhance the device's power management capabilities. By complementing the vertical power delivery system, these horizontal power delivery chiplets distribute power laterally, reducing voltage drops and improving energy efficiency. The combination of vertical and horizontal power delivery systems ensures that all functional layers within the die stack 204 receive consistent and adequate power, regardless of their position.

In some embodiments, the high-bandwidth connections enabled by the device's vertical and horizontal interconnect layers support rapid data transfer with minimal latency. These connections, interfacing with interposer 228 or alternative horizontal high-bandwidth wiring layers, ensure that the device can handle large volumes of data efficiently. The short connection paths reduce signal propagation delays, enabling real-time processing and communication between critical components such as CPUs, GPUs, and memory units.

In some embodiments, to achieve very high bandwidth with low latency, the device employs connections less than 25 microns per layer. This fine-grained connectivity allows components to be positioned in close proximity, enhancing their interaction and reducing energy losses. This configuration is particularly beneficial for applications requiring high-speed computation and seamless data integration, such as machine learning, data analytics, and cloud computing.

In some embodiments, electrical shielding and magnetic shielding are incorporated to reduce electromagnetic interference (EMI), which ensures stable and reliable signal and power transmission. Cooling structures within these chips dissipate heat effectively, ensuring the long-term reliability of the semiconductor device. In some embodiments, electrical and optical communication links provide seamless integration of electrical and optical technologies, allowing high-speed data transfer between critical components. The use of optical links minimizes latency and power consumption while enabling the device to handle data-intensive applications such as artificial intelligence (AI), high-performance computing, and large-scale cloud infrastructure.

In some embodiments, the die stack 204 includes memory modules designed to enhance the device's versatility and performance. These modules can include standard off-the-shelf memory or custom-designed memory solutions. The regular pass-throughs for power and signals integrated into the die stack ensure compatibility with existing technologies while enabling efficient communication and power delivery throughout the stack. This adaptability allows the device to be incorporated into a variety of applications without extensive reconfiguration.

In some embodiments, the integration of optical physical layer (PHY) within the interposer 228 and cooling units further extends the device's capabilities. These optical components support high-speed, low-power data transmission, enabling the semiconductor device to address the demands of modern high-performance applications. The combination of optical and electrical technologies ensures a balance of performance, power efficiency, and scalability.

In some embodiments, the disclosed semiconductor device introduces features that include the integration of more chips within each stack, resulting in overall higher circuit density and greater power density, which leverages advanced technology nodes to meet the increasing demands of 3D stacked architectures and multiple 3D stacks of thinned chips. As chip voltages continue to decrease, managing these voltages becomes crucial to avoid voltage droop tolerances and to support the substantial current loads required by these new architectures. The design incorporates thermal conductive elements and/or micro-channel cooling elements strategically placed within orthogonal members at the stack perimeter, between stacks, and even within the chip stacks themselves. These features collectively enhance the thermal performance and reliability of the device.

The architecture supports heterogeneous integration of diverse chips, including microprocessor chips such as CPUs, GPUs, and ASICs or accelerators, alongside memory chips. Such an integration provides both high bandwidth and robust power and ground connections for delivery, signal communication, and effective thermal management. Cooling channels can be implemented at the bottom and/or top of the stacks, while orthogonal connections are used for power, ground, and signal routing. Additionally, thermal materials are embedded within these orthogonal connections and distributed throughout the chiplet stacks to optimize heat dissipation and thermal balance.

Integrated horizontal power delivery and ground distribution are incorporated at the top and/or bottom of the chiplet stacks. Such elements are connected to orthogonal inductors placed at the perimeter of the stacks, the package perimeter, and between the chip stacks, as well as within individual chip stacks. The interconnected power delivery system provides efficient energy distribution and reduces voltage drops, enabling reliable operation of the high-density architecture.

The architecture enhances performance, particularly for applications such as AI microprocessors and memory modules. By increasing the density of signal communication links, the semiconductor device achieves lower power consumption and reduced latency. The use of thinned chips further improves signal integrity and interconnection density. Simultaneously, the design addresses power delivery, cooling solutions, and the integration of multiple 3D stacks. Features such as signal routing, power delivery, voltage regulation, decoupling capacitors, inductance control, and step-down voltage levels are integrated to maintain stable operation.

Thermal management is another aspect of this architecture, which provides module-level and heterogeneous stack-level cooling solutions, including thermal isolation to prevent or minimize temperature gradients between devices, stacks, and components. This isolation helps avoid reliability issues and functional limitations that could arise due to uneven temperature distribution.

In some embodiments, for efficient thermal management, processors are located at the top or the bottom of 3D chip/chiplet stacks to ensure direct contact with a heat spreader, a heat sink, or the interposer 228. This arrangement enhances heat dissipation, allowing thermal energy generated by the processors to be efficiently transferred to external cooling components. By situating processors in close proximity to these thermal management elements, the semiconductor device achieves improved temperature regulation and operational stability.

In some embodiments, the semiconductor device includes integrated power delivery systems, thermal management solutions, and interconnect structures that support vertical and horizontal connections for power, ground, signals, and thermal conductivity. These interconnects can incorporate inductors, capacitors, and thermal conductive elements to optimize both electrical and thermal performance. The thermal interconnects are specifically designed to include thermal conductors and shielding for inductors, ensuring that heat is managed effectively without impacting the device's electromagnetic integrity.

The semiconductor device shown in FIG. 2A can include the following configuration: memory, processor, and a horizontal power delivery chip. In this exemplary configuration, the memory is positioned at the top of the stack, with the processor located in the middle and the horizontal power delivery chip at the base. This configuration leverages the relative thermal and electrical characteristics of each component. The memory, which generates less heat, is placed farther from the primary cooling systems, allowing it to maintain stable operation without significant thermal interference. The processor, positioned centrally, benefits from efficient access to both the memory above and the horizontal power delivery chip below, optimizing data transfer and power delivery while minimizing latency.

An alternate configuration is also possible, where the horizontal power delivery chip is located at the top, followed by the processor in the middle, and the memory at the base. This arrangement can be advantageous in scenarios where the power delivery chip requires direct integration with top-mounted cooling solutions, such as heat sinks or cold plates. Placing the memory at the bottom ensures closer proximity to interposers or other interface layers, enhancing its connection to external systems and improving overall data flow efficiency. These configurations demonstrate the flexibility of the semiconductor device design, allowing for optimization based on specific application requirements. Whether prioritizing thermal management, power efficiency, or data routing, the device can be tailored to achieve high performance across a variety of use cases.

Referring to FIG. 2B now, in some embodiments, thermal interface materials (TIM) are utilized to enhance heat transfer between critical components. These materials are engineered with tailored conductivity properties to accommodate high or low thermal resistance (K) requirements. By optimizing the gap and thermal gradients, the TIM 252 facilitates efficient heat dissipation, minimizing thermal stress and preventing performance degradation across the device. Managed conductivity properties ensure that localized hotspots are mitigated, contributing to the overall reliability of the 3D chip/chiplet stacks. The semiconductor device can further include a heat spreader 254.

In some embodiments, the semiconductor device includes vias and interconnects that support vertical connections for power, ground, and signals. These interconnects are designed to function seamlessly with thermal interconnects, enabling efficient heat transfer alongside electrical connectivity. The thermal interconnects can be positioned at the bottom of each stack, at the top of each stack, or at both locations to provide comprehensive thermal management. This configuration ensures that thermal energy is effectively dissipated regardless of the stack's orientation or operational intensity.

In some embodiments, the integration of vertical and horizontal interconnects allows the semiconductor device to deliver robust performance while maintaining efficient thermal regulation. By combining electrical and thermal interconnects with advanced thermal materials, the device supports high-power, high-density applications while preventing overheating and ensuring long-term reliability. The synergy between thermal and electrical systems within the device represents a significant advancement in the design of 3D chip/chiplet stacks for modern semiconductor technologies.

FIG. 2C illustrates a semiconductor device, in accordance with some embodiments. The semiconductor device includes input current feeding from vertical power delivery chips to a cold plate 274 and a power delivery unit 276. This configuration enables effective energy distribution while maintaining optimal operating temperatures for the device. In some embodiments, the semiconductor device includes solder interconnects 278 for input current feeding. The solder interconnects 278 provide connections between vertical power delivery chips, the cold plate 274, and the power delivery unit 276. The interconnects are designed to support segmented multiple voltages, ensuring that various voltage levels are efficiently routed to different components. This design enhances the device's adaptability to diverse operational requirements.

In some embodiments, the cold plate 274 integrated within the device are configured as single-phase or two-phase cooling systems. The cold plate 274 dissipate heat generated during device operation, ensuring reliable thermal performance across the semiconductor device. The inclusion of advanced cooling systems contributes to the stability and longevity of the device under high-power or high-density conditions. In some embodiments, the semiconductor device includes one or more coils 280 and wire levels 282 associated with each vertical power delivery chip 272. The wire levels 282 are segmented by copper (Cu) layers, with separate voltage levels allocated to each layer. This segmentation facilitates efficient voltage routing and minimizes power losses, enabling the device to support high-performance applications with diverse power requirements.

In some embodiments, the semiconductor device integrates power delivery, thermal management, and interconnect solutions that provide both vertical and horizontal connections 284. These connections support power, ground, signals, inductors, capacitors, and thermal interconnects. The thermal interconnects include thermal conductors and shielding for inductors, ensuring that heat is effectively managed without compromising electromagnetic integrity.

In some embodiments, the interconnections within the semiconductor device can include various technologies, such as solder interconnects 278, Cu—Cu bonds, metal-to-metal connections, hybrid bonds, or alternate bonding methods. These interconnections are designed to ensure robust electrical and thermal conductivity while supporting the high-density integration of the semiconductor device. The use of advanced interconnection technologies enhances the reliability and scalability of the device, making it suitable for next-generation semiconductor applications.

FIG. 2D illustrates a semiconconductor device without conversion in vertical power distribution in chips, in accordance with some embodiments. In some embodiments, the semiconductor device includes input current feeding from vertical power delivery chips to cold plate 274 and a power delivery unit 286. This specific design facilitates direct and efficient transfer of electrical power to critical components within the device, ensuring operational reliability under varying load conditions. In such embodiments, the power distribution process is streamlined, as no voltage conversion is conducted within the vertical power delivery chips themselves. This omission reduces complexity and potential inefficiencies associated with additional conversion steps, resulting in improved overall energy management.

The semiconductor device further incorporates solder interconnects 278 that link the vertical power delivery chips to both the cold plate 274 and the power delivery unit 286. These interconnects are segmented to handle multiple voltage levels, allowing for precise and customized power distribution across various components. By isolating voltage levels, the design minimizes power loss and interference, supporting a wide range of operational scenarios and ensuring that each segment receives the appropriate power supply.

Cold plates within the device are available in either single-phase or two-phase configurations. Single-phase cold plates provide a straightforward and dependable cooling solution, effectively managing moderate thermal loads. Two-phase cold plates, on the other hand, offer superior thermal performance by utilizing phase-change mechanisms to dissipate heat more efficiently. This flexibility in cooling solutions enables the semiconductor device to maintain optimal operating temperatures, even under high-performance or high-density conditions.

In some embodiments, the vertical power delivery chips are equipped with one or more coils 280 and wire levels 282, each of which is segregated by copper layers. These wire levels 282 are designed to accommodate different voltage levels, ensuring precise and stable power delivery to various sections of the semiconductor device. The use of copper as the primary conductor enhances electrical conductivity while minimizing resistance, thereby optimizing the device's energy efficiency and performance. The semiconductor device can include an intermediate voltage, V intermediate 292, and an intermediate ground, GND intermediate 294.

This advanced configuration enables the semiconductor device to meet the demanding power and thermal management requirements of modern electronic systems. By integrating features such as segmented solder interconnects, adaptable cold plate designs, and meticulously structured wire levels, the device achieves a high degree of efficiency, reliability, and adaptability, making it suitable for a wide range of applications in cutting-edge technology fields. FIG. 2E illustrates a semiconductor device with power distribution and conversion in vertical power delivery chips, in accordance with some embodiments. In some embodiments, the semiconductor device includes power distribution and conversion within vertical power delivery chips. These vertical power delivery chips are designed to integrate both the supply and transformation of electrical power, ensuring that the appropriate voltage and current levels are delivered to various components within the device. The power distribution feature allows for efficient routing of electrical energy from input sources to different areas of the device, while the power conversion functionality provides the necessary regulation to match specific operational requirements.

By consolidating these two critical functions into the vertical power delivery chips, the semiconductor device achieves enhanced efficiency and compactness. This integration eliminates the need for external conversion units, reducing the overall footprint and simplifying the design. Furthermore, the capability to dynamically regulate power ensures stability under varying load conditions, making the device suitable for high-performance applications. The inclusion of both distribution and conversion within the vertical power delivery chips represents a significant advancement in semiconductor technology, supporting next-generation electronic systems with improved energy management and operational flexibility. The semiconductor device can include an inductor 290.

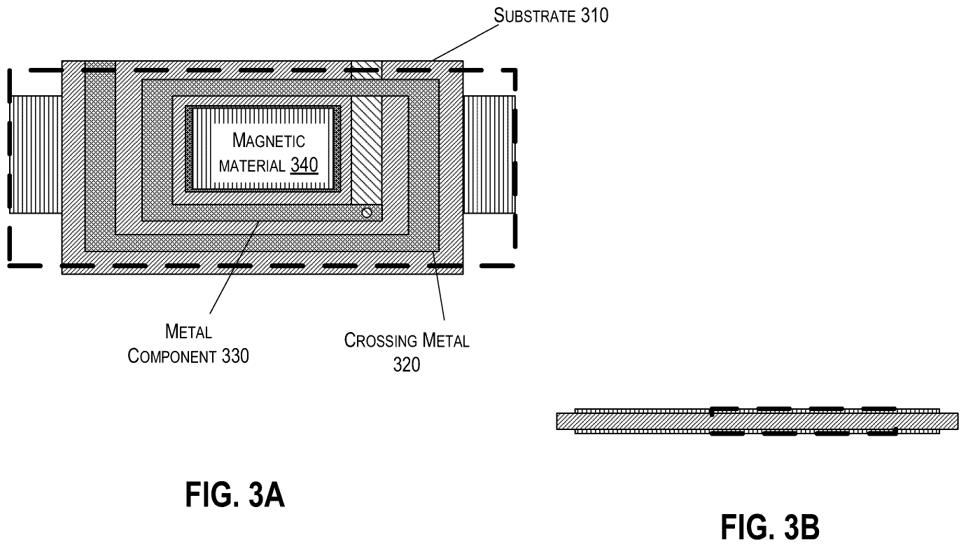

FIGS. 3A-3B illustrate an exemplary power delivery chip of the semiconductor device, in accordance with some embodiments. FIG. 3A shows a top view of the power delivery chip including an electrically insulating and high thermal conductivity substrate 310, which can be fabricated from materials such as aluminum nitride (AlN), silicon carbide (SiC), diamond, or other suitable alternatives. These materials are chosen for their exceptional thermal conductivity, enabling efficient dissipation of heat generated during operation, while simultaneously providing electrical insulation to prevent interference between conductive elements. Additionally, the power delivery chip includes a crossing metal 320, which can be implemented as a copper (Cu) coil. This crossing metal plays a role in the chip's functionality, acting as an inductor or part of a transformer to facilitate energy transfer within the chip. Copper is preferred due to its excellent electrical conductivity, which minimizes energy losses and enhances the efficiency of power delivery. Magnetic materials 340 can be located in the middle of the power delivery chiplet.

The power delivery chip further incorporates another metal component 330, also implemented as a copper (Cu) coil. This component is often used in tandem with the crossing metal 320 to create electromagnetic fields essential for inductive coupling or voltage transformation. By utilizing multiple coils, the chip can achieve high levels of power efficiency and stability, making it suitable for applications requiring precise voltage regulation and energy distribution. Together, these components—the high thermal conductivity substrate 310, the crossing metal 320, and the metal component 330—form a cohesive system that enables the power delivery chip to operate effectively under high-performance conditions. The integration of these materials and structures ensures that the chip can handle significant power loads while maintaining thermal stability and electrical reliability, making it a critical component of advanced semiconductor devices. FIG. 3B illustrates a cross section of the power delivery chip shown in FIG. 3A.

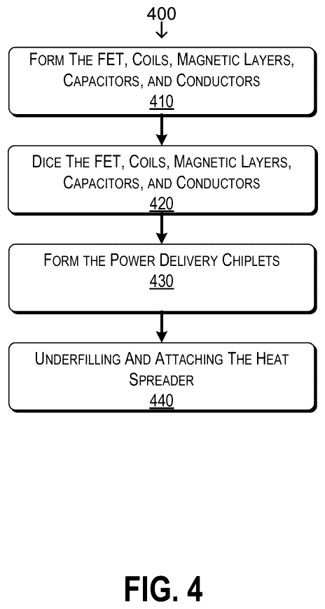

FIG. 4 illustrates a block diagram of a method 400 for forming the semiconductor device, in accordance with some embodiments. As shown by block 410, FETs, coils, magnetic layers, decoupling capacitors and conductors are formed.

As shown by block 420, the FETs, coils, magnetic layers, decoupling capacitors and conductors are diced into chip size.

As shown by block 430, the power delivery chips are formed on the side of the chip stacks.

As shown by block 440, underfilling is performed and the heat spreader is attached.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
at least one die stack; and
one or more peripheral interconnect structures surrounding one or more sides of the at least one die stack, wherein the one or more peripheral interconnect structures are assembled in a perpendicular orientation to a functional circuit layer of the at least one die stack.

2. The semiconductor device of claim, 1, wherein the one or more peripheral interconnect structures comprise at least one of: a peripheral power delivery interconnect structure, a peripheral cooling interconnect structure, a peripheral clocking interconnect structure, or a peripheral signal interconnect structure.

3. The semiconductor device of claim 1, further comprising: a power delivery chiplet located within the at least one die stack, wherein the power delivery chiplet is connected at a periphery of the at least one die stack to at least one of the one or more peripheral interconnect structures.

4. The semiconductor device of claim 1, further comprising a substrate, wherein the substrate is at least one of: a glass, silicon, an organic electrically insulating material, or an inorganic electrically insulating material.

5. The semiconductor device of claim 1, further comprising a substrate, wherein:
the substrate is a thermal conductive material;
the substrate is at least one of: diamond, AlN, or SiN; and
the substrate comprises oscillating heat pipes.

6. The semiconductor device of claim 3, wherein:
the power delivery chiplet is a horizontal power delivery chiplet; and
the power delivery chiplet is integrated in the one or more die stacks.

7. The semiconductor device of claim 1, further comprising:
circuit layers through one or more vertical connections in the at least one die stack; and
an interposer,
wherein
the interposer is a horizontal high-bandwidth wiring layer, and
the circuit layers comprise at least one of: high bandwidth (BW) layers or short connection layers.

8. The semiconductor device of claim 1, further comprising:
circuit stack layers through one or more horizontal connections in the at least one die stack; and
an interposer,
wherein
the interposer is a horizontal high-bandwidth wiring layer; and
the circuit stack layers comprise at least one of: high bandwidth (BW) layers and short connection layers.

9. The semiconductor device of claim 1, further comprising high-bandwidth circuit layers with low latency, wherein the high-bandwidth circuit layers comprise connections with less than 25 microns per layer.

10. The semiconductor device of claim 1, wherein the one or more die stacks comprise at least one of: a transistor, coils, magnetic layers, decoupling capacitors, electrical conductor elements, or thermal conducting elements.

11. The semiconductor device of claim 3, wherein the power delivery chiplet comprises inductors, power delivery circuits, signal delivery circuits, electrical shielding, magnetic shielding, or cooling structures.

12. The semiconductor device of claim 1, further comprising electrical and optical communication links, wherein the electrical and optical communication links are located in at least one of: an interposer, a cooling unit, or a power feed unit.

13. The semiconductor device of claim 1, wherein the at least one die stack comprises at least one of: a memory, a pass-throughs of power line, or a pass-through of signal line.

14. A method for fabrication of a semiconductor device, the method comprising:
forming at least one die stack; and
forming one or more peripheral interconnect structures surrounding one or more sides of the at least one die stack, wherein the one or more peripheral interconnect structures are assembled in a perpendicular orientation to a functional circuit layer of the at least one die stack.

15. The method of claim 14, further comprising:
forming a power delivery chiplet located within the at least one die stack; and
connecting the power delivery chiplet at a periphery of the at least one die stack to at least one of the one or more peripheral interconnect structures.

16. The method of claim 14, further comprising forming a substrate, wherein the substrate is at least one of: a glass, silicon, an organic electrically insulating material, or an inorganic electrically insulating material.

17. The method of claim 14, further comprising forming a substrate, wherein:
the substrate is a thermal conductive material;
the substrate is at least one of: diamond, AlN, or SiN, and
the substrate comprises oscillating heat pipes.

18. The method of claim 14, further comprising:
forming circuit layers through one or more vertical connections in the at least one die stack; and
forming an interposer,
wherein:
the interposer is a horizontal high-bandwidth wiring layer; and
the circuit layers comprise at least one of: high bandwidth (BW) layers or short connection layers.

19. The method of claim 14, further comprising:
forming circuit stack layers through one or more horizontal connections in the at least one die stack; and
forming an interposer,
wherein:
the interposer is a horizontal high-bandwidth wiring layer; and
the circuit layers comprise at least one of: high bandwidth (BW) layers and short connection layers.

20. A semiconductor device, comprising:
a die stack; and
a peripheral power delivery interconnect chiplet surrounding one or more sides of the die stack,
wherein:
the power delivery chiplet is a horizontal power delivery chiplet; and
the power delivery chiplet is integrated in the die stack.
